(19) United States
(12) Patent Application Publication
(10) Pub. No.: US 2025/0016991 A1
(43) Pub. Date: Jan. 9, 2025

(54) INTEGRATED CIRCUIT MEMORY DEVICES HAVING ENHANCED MEMORY CELL LAYOUTS

(71) Applicant: Samsung Electronics Co., Ltd., Suwon-si (KR)

(72) Inventors: Jaejoon Song, Suwon-si (KR); Julpin Park, Suwon-si (KR); Deokhwan Choi, Suwon-si (KR)

(21) Appl. No.: 18/757,681

(22) Filed: Jun. 28, 2024

(30) Foreign Application Priority Data
Jul. 4, 2023 (KR) 10-2023-0086653

(51) Int. Cl. H10B 12/00

(52) U.S. Cl. CPC H10B 12/482; H10B 12/315; H10B 12/488

(57) ABSTRACT

An integrated circuit memory device (e.g., DRAM) includes a substrate having a bit line thereon, and an electrically insulating region having a first opening therein, which exposes a first portion of the bit line. A first semiconductor active layer is provided, which lines first and second opposing sidewalls of the first opening and the exposed first portion of the bit line, such that a direct electrical connection is provided between the exposed first portion of the bit line and a portion of the first semiconductor active layer extending between the first and second sidewalls of the first opening. A first word line is provided on a first portion of the first semiconductor active layer extending opposite the first sidewall of the first opening, and a second word line is provided on a second portion of the first semiconductor active layer extending opposite the second sidewall of the first opening.

### REFERENCE TO PRIORITY APPLICATION

This application claims priority under 35 U.S.C. § 119 to Korean Patent Application No. 10-2023-0086653, filed Jul. 4, 2023, the disclosure of which is hereby incorporated herein by reference.

### BACKGROUND

The inventive concept relates to semiconductor devices and, more specifically, to integrated circuit memory devices.

With the continuing downscaling of semiconductor devices, the size of dynamic random access memory (DRAM) devices is also decreasing. In a DRAM device having a 1T-1C structure in which one capacitor is connected to one transistor, there is a problem in that leakage current through a channel area typically increases as the device becomes smaller. To reduce leakage current, a vertical channel transistor that uses an oxide semiconductor material as a channel layer has been proposed.

### SUMMARY

The inventive concept provides a semiconductor device, such as a DRAM device, having excellent electrical performance.

According to an aspect of the inventive concept, there is provided a semiconductor device including: a bit line extending in a first horizontal direction on a substrate, and a mold structure disposed on the bit line and including a mold opening extending in a second direction perpendicular to the first horizontal direction. The mold structure may include a mold insulating layer, a cover insulating layer disposed on the mold insulating layer, and an interface insulating layer disposed on an upper surface of and on at least a portion of a sidewall of the cover insulating layer. An active semiconductor layer is also provided, and includes a first portion disposed on an inner wall of the mold opening of the mold structure and extending in a vertical direction perpendicular to an upper surface of the substrate, and a second portion connected to the bottom of the first portion and extending in the first horizontal direction. In some embodiments, the second portion is disposed on an upper surface of the bit line, and the first portion includes a first sidewall in contact with a sidewall of the mold opening and a second sidewall extending opposite to the first sidewall. A word line is also provided, and is disposed on the second sidewall of the active semiconductor layer and extends in the second horizontal direction. A gate insulating layer is provided between the active semiconductor layer and the word line, and a landing pad is provided, which extends on an upper surface of the first portion of the active semiconductor layer.

According to further embodiments, a semiconductor device is provided, which includes a bit line extending in a first horizontal direction on a substrate, a mold structure disposed on the bit and including a mold opening extending in a second direction perpendicular to the first horizontal direction, with the mold structure including a mold insulating layer, a cover insulating layer disposed on the mold insulating layer, and an interface insulating layer disposed on an upper surface of and on at least a portion of a sidewall of the cover insulating layer. An active semiconductor layer is provided, which includes a first portion disposed on an inner wall of the mold opening of the mold structure and extending in a vertical direction perpendicular to an upper surface of the substrate, and a second portion connected to the bottom of the first portion and extending in the first horizontal direction. In some embodiments, the second portion is disposed on an upper surface of the bit line, and the first portion includes a first sidewall that is in contact with a sidewall of the mold opening and a second sidewall opposite to the first sidewall. A word line is provided, which is disposed on the second sidewall of the active semiconductor layer and extends in the second horizontal direction. A gate insulating layer is provided, which is disposed between the active semiconductor layer and the word line. A landing pad is provided, which is connected to an upper surface of the first portion of the active semiconductor layer. In some embodiments, the landing pad may include an upper portion disposed on an upper surface of the mold structure and a bottom portion connected to the upper portion and disposed in a landing pad recess space, and a bottom surface of the bottom portion of the landing pad may be disposed at a same level as a bottom surface of the interface insulating layer.

According to another aspect of the inventive concept, there is provided a semiconductor device including: a bit line extending in a first horizontal direction on a substrate; a mold structure disposed on the bit line and including a mold opening extending in a second direction perpendicular to the first horizontal direction, the mold structure including a mold insulating layer, a cover insulating layer disposed on the mold insulating layer, and an interface insulating layer disposed on an upper surface of and on at least a portion of a sidewall of the cover insulating layer; an active semiconductor layer including a first portion disposed on an inner wall of the mold opening of the mold structure and extending in a vertical direction perpendicular to an upper surface of the substrate, and a second portion connected to the bottom of the first portion and extending in the first horizontal direction, wherein the second portion is disposed on an upper surface of the bit line, and the first portion includes a first sidewall that is in contact with a sidewall of the mold opening and a second sidewall opposite to the first sidewall, and the active semiconductor layer has an upper surface disposed at a lower level than an upper surface of the mold structure; a word line disposed on the second sidewall of the active semiconductor layer and extending in the second horizontal direction; a gate insulating layer disposed between the active semiconductor layer and the word line; a buried insulating layer disposed on a sidewall of the word line and filling the mold opening; a landing pad connected to an upper surface of the first portion of the active semiconductor layer, the landing pad including an upper portion disposed on the upper surface of the mold structure and a bottom portion connected to the upper portion and disposed in a landing pad recess space; and a storage node connected to the landing pad, wherein the interface insulating layer extends from the upper surface of the cover insulating layer onto a sidewall of the cover insulating layer disposed in the landing pad recess space.

According to still further embodiments of the invention, an integrated circuit memory device is provided, which includes a substrate having a bit line (BL) thereon, and an electrically insulating region having a first opening therein, which exposes a first portion of the bit line. A first semiconductor active layer is also provided, which lines first and second opposing sidewalls of the first opening and the exposed first portion of the bit line, such that a direct electrical connection is provided between the exposed first portion of the bit line and a portion of the first semiconductor active layer extending between the first and second sidewalls of the first opening. A first word line is provided on a first portion of the first semiconductor active layer extending opposite the first sidewall of the first opening, and a second word line is provided on a second portion of the first semiconductor active layer extending opposite the second sidewall of the first opening. Advantageously, a portion of the first word line extending opposite the first portion of the first semiconductor active layer operates as a gate electrode of an access transistor of a first memory cell, and a portion of the second word line extending opposite the second portion of the first semiconductor active layer operates as a gate electrode of an access transistor of a second memory cell.

### BRIEF DESCRIPTION OF THE DRAWINGS

Embodiments will be more clearly understood from the following detailed description taken in conjunction with the accompanying drawings in which:

FIG. 1 is a layout diagram illustrating a semiconductor device according to embodiments;

FIG. 2 is an enlarged layout view of a portion of a cell array area of FIG. 1;

FIG. 3 is a cross-sectional view taken along line A1-A1′ of FIG. 2;

FIG. 4 is a cross-sectional view taken along line A2-A2′ of FIG. 2;

FIG. 5 is an enlarged view of portion CX1 of FIG. 3;

FIGS. 6 and 7 are cross-sectional views illustrating a semiconductor device according to embodiments;

FIG. 8 is an enlarged view of portion CX1 of FIG. 6;

FIG. 9 is a cross-sectional view illustrating a semiconductor device according to embodiments;

FIG. 10 is an enlarged view of portion CX1 of FIG. 9;

FIG. 11 is a cross-sectional view illustrating a semiconductor device according to embodiments; and

FIGS. 12A to 23 are schematic diagrams showing a method of manufacturing a semiconductor device according to embodiments, where FIGS. 12A, 13A, 14, 15A, 16A, 17 to 21A, 22, and 23 are cross-sectional views taken along line A1-A1′ of FIG. 2, FIGS. 15B, 16B, and 21B are cross-sectional views taken along line A2-A2′ of FIG. 2, and FIGS. 12B, 13B, 15C, and 16C are top views of FIGS. 12A, 13A, 15A, and 16A, and in FIGS. 12A to 23, the same reference numerals as those in FIGS. 1 to 11 indicate the same components.

### DETAILED DESCRIPTION OF THE EMBODIMENTS

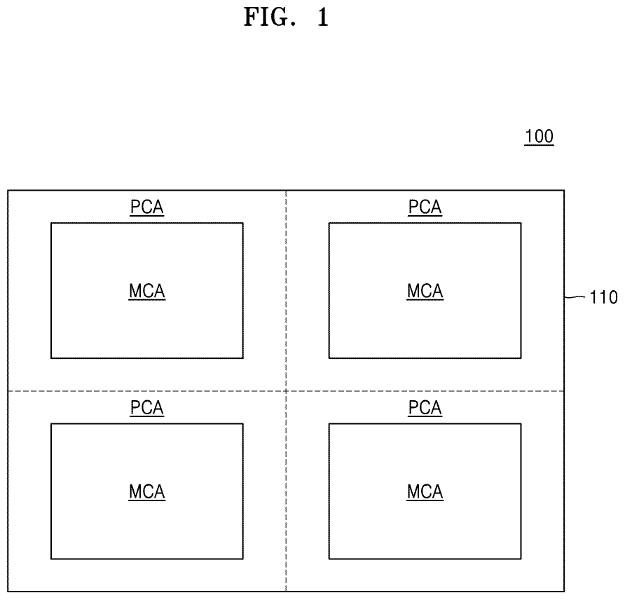

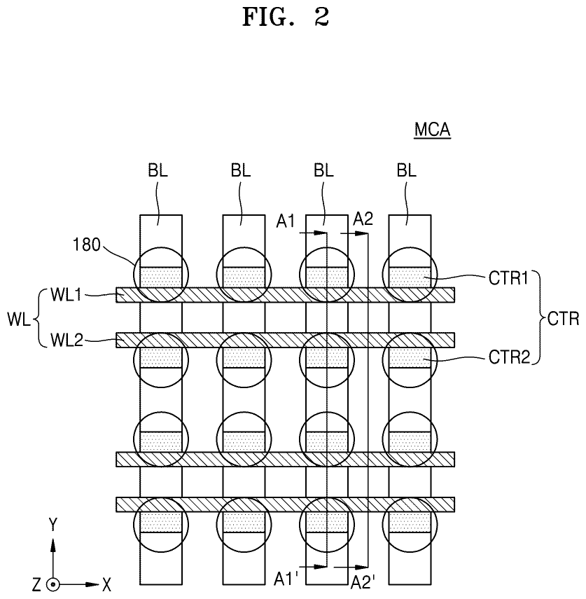

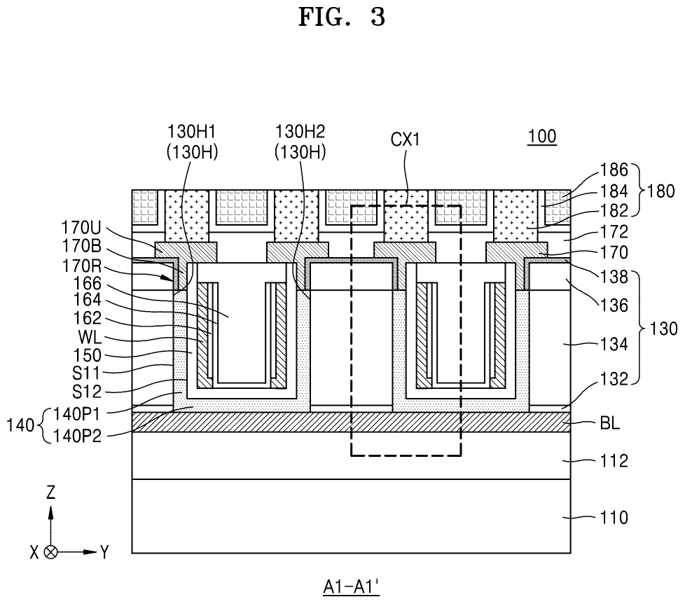

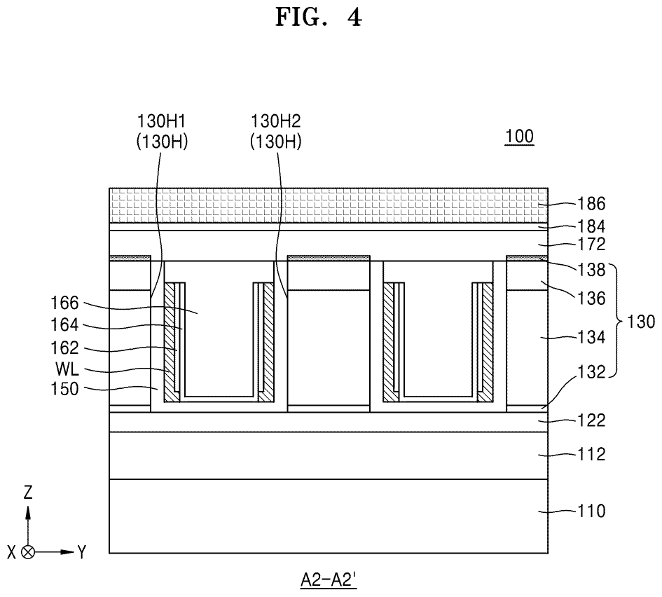

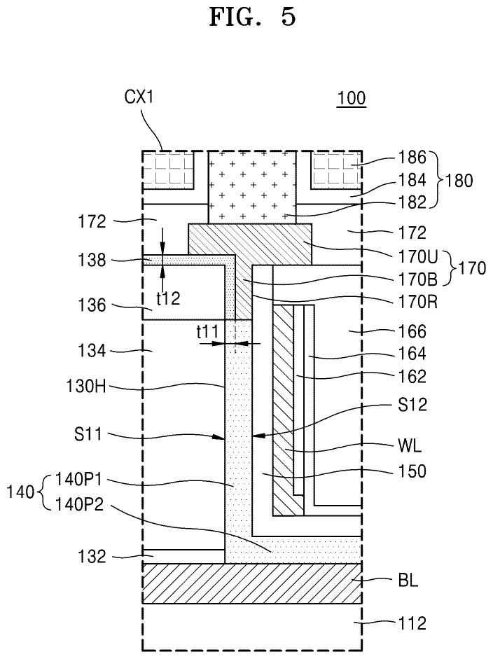

FIG. 1 is a layout diagram illustrating a semiconductor device 100 according to embodiments, and FIG. 2 is an enlarged layout diagram of a portion of a cell array area MCA of FIG. 1. In addition, FIG. 3 is a cross-sectional view taken along line A1-A1′ of FIG. 2, FIG. 4 is a cross-sectional view taken along line A2-A2′ of FIG. 2, and FIG. 5 is an enlarged view of portion CX1 of FIG. 3.

Referring to FIGS. 1 to 5, the semiconductor device 100 may include a substrate 110 including a cell array area MCA and a peripheral circuit area PCA. In some embodiments, the cell array area MCA may be a memory cell area of a dynamic random access memory (DRAM) device, and the peripheral circuit area PCA may be a core area or a peripheral circuit area of a DRAM device. For example, the peripheral circuit area PCA may include peripheral circuit transistors (not shown) for transmitting signals and/or power to a memory cell array included in the cell array area MCA. In embodiments, the peripheral circuit transistors (not shown) may form various circuits such as a command decoder, control logic, an address buffer, a row decoder, a column decoder, a sense amplifier, and a data input/output circuit.

As illustrated in FIG. 2, in the cell array area MCA of the substrate 110, a plurality of word lines WL extending in a first horizontal direction X and a plurality of bit lines BL extending in a second horizontal direction Y may be arranged. A plurality of cell transistors CTR may be arranged at intersections of the plurality of word lines WL and the plurality of bit lines BL. A plurality of storage nodes 180 may be arranged on each cell transistor CTR.

The plurality of word lines WL may include a first word line WL1 and a second word line WL2 alternately arranged in the second horizontal direction Y, and the plurality of cell transistors CTR may include a first cell transistor CTR1 and a second cell transistor CTR2 arranged alternately in the second horizontal direction Y. The first cell transistor CTR1 may be disposed adjacent to the first word line WL1, and the second cell transistor CTR2 may be disposed adjacent to the second word line WL2.

The first cell transistor CTR1 and the second cell transistor CTR2 may have a mirror symmetrical structure with respect to each other. For example, the first cell transistor CTR1 and the second cell transistor CTR2 may have a mirror symmetrical structure with respect to a center line between the first cell transistor CTR1 and the second cell transistor CTR2 extending in the first horizontal direction X.

As illustrated in FIG. 3, a lower insulating layer 112 may be disposed on the substrate 110. The substrate 110 may include silicon, for example, single crystalline silicon, polycrystalline silicon, or amorphous silicon. In some other embodiments, the substrate 110 may include at least one selected from Ge, SiGe, SiC, GaAs, InAs, and InP. In some embodiments, the substrate 110 may include a conductive region, for example, a well doped with an impurity, or a structure doped with an impurity. The lower insulating layer 112 may include an oxide film, a nitride film, or a combination thereof.

In some embodiments, a peripheral circuit structure may be disposed on the substrate 110, and the lower insulating layer 112 may be disposed to cover the peripheral circuit structure. The peripheral circuit structure may include, but is not limited to, a sense amplifier electrically connected to the bit line BL and/or a sub-word line driver electrically connected to the word line WL.

A bit line BL extending in the second horizontal direction Y may be disposed on the lower insulating layer 112. In embodiments, the bit line BL may include Ti, TiN, Ta, TaN, Mo, Ru, W, WN, TiSIN, WSiN, polysilicon, or a combination thereof. A bit line isolation insulating layer 122 extending in the second horizontal direction Y may be disposed on a sidewall of the bit line BL. For example, the bit line isolation insulating layer 122 may fill a space between two adjacent bit lines BL and may be formed at the same height as the bit lines BL.

A mold structure 130 may be disposed on the bit line BL and the bit line isolation insulating layer 122. The mold structure 130 may include an etch stop layer 132, a mold insulating layer 134, a cover insulating layer 136, and an interface insulating layer 138. In some embodiments, the etch stop layer 132 may have a relatively small thickness and be disposed on upper surfaces of the bit line BL and the bit line isolation insulating layer 122. The etch stop layer 132 may include silicon nitride.

In some embodiments, the mold insulating layer 134 may be disposed on the etch stop layer 132. The mold insulating layer 134 may be formed to have a relatively large height. In embodiments, the mold insulating layer 134 may include silicon oxide.

In embodiments, the cover insulating layer 136 may be disposed on an upper surface of the mold insulating layer 134. The cover insulating layer 136 may include a material having an etch selectivity with that of the mold insulating layer 134. In embodiments, the cover insulating layer 136 may include silicon nitride.

In embodiments, the interface insulating layer 138 may be disposed on an upper surface of the cover insulating layer 136 and on a portion of a sidewall of the cover insulating layer 136. In some embodiments, the interface insulating layer 138 may include silicon oxynitride or silicon oxide. In some embodiments, the interface insulating layer 138 may include a material layer formed by oxidizing a portion of the cover insulating layer 136 as a result of performing an oxygen annealing process on the upper surface of the cover insulating layer 136.

In embodiments, the interface insulating layer 138 disposed on the sidewall of the cover insulating layer 136 may have a first thickness t11, and the interface insulating layer 138 disposed on the upper surface of the cover insulating layer 136 may have a second thickness t12. In embodiments, the first thickness t11 and the second thickness t12 may be in a range from about several angstroms to about tens of angstroms. In some embodiments, the first thickness t11 may be substantially equal to the second thickness t12. In some embodiments, the first thickness t11 may be less than the second thickness t12.

In embodiments, the mold structure 130 may include a plurality of mold openings 130H. The plurality of mold openings 130H may extend in the first horizontal direction X, and an upper surface of the bit line BL may be exposed at the bottom of each of the plurality of mold openings 130H. For example, the plurality of mold openings 130H may include a first sidewall 130H1 and a second sidewall 130H2, and the first sidewall 130H1 and the second sidewall 130H2 may be spaced apart from each other and extend in the first horizontal direction X.

A plurality of active semiconductor layers 140 may be disposed on inner walls of the plurality of mold openings 130H. Each of the plurality of active semiconductor layers 140 may include a first portion 140P1 and a second portion 140P2. The first portion 140P1 may refer to a portion extending in a vertical direction Z on the first sidewall 130H1 and the second sidewall 130H2 of the mold openings 130H. The second portion 140P2 may refer to a portion that is disposed at the bottom of the mold opening 130H, disposed on the bit line BL, and in contact with the upper surface of the bit line BL. For example, each of the plurality of active semiconductor layers 140 may have a U-shaped vertical cross-section.

The first portion 140P1 of the active semiconductor layer 140, which is disposed adjacent to the first sidewall 130H1 of the mold opening 130H, may function as a vertical channel layer of the first cell transistor CTR1, and the first portion 140P1 of the active semiconductor layer 140, which is disposed adjacent to the second sidewall 130H2 of the mold opening 130H, may function as a vertical channel layer of the second cell transistor CTR2. Accordingly, within one mold opening 130H, the first cell transistor CTR1 and the second cell transistor CTR2 may be arranged in a mirror symmetrical shape with each other.

The first portion 140P1 of the plurality of active semiconductor layers 140 may include a first sidewall S11 and a second sidewall S12 that are opposite to each other, and the first sidewall S11 may be in contact with the mold insulating layer 134. In embodiments, each of the plurality of active semiconductor layers 140 may have an upper surface disposed at a lower level than an upper surface of the mold structure 130 and disposed at the same level as a bottom surface of the cover insulating layer 136. In some embodiments, each of the plurality of active semiconductor layers 140 may have an upper surface disposed at a lower level than the bottom surface of the cover insulating layer 136.

In embodiments, the plurality of active semiconductor layers 140 may include an oxide semiconductor material. For example, the plurality of active semiconductor layers 140 may include at least one of indium gallium zinc oxide (InₓGa_{y}Zn_{z}O), indium tungsten oxide (InₓWyO), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), and magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), and tin oxide (SnₓO). In some embodiments, in addition to the materials described above, the plurality of active semiconductor layers 140 may include an oxide semiconductor material having a greater band gap energy than that of silicon.

A gate insulating layer 150 may be disposed on the second sidewall S12 of the plurality of active semiconductor layers 140. For example, the gate insulating layer 150 may be conformally arranged on the second sidewall S12 of the first portion 140P1 and an upper surface of the second portion 140P2 of the plurality of active semiconductor layers 140.

In some embodiments, the gate insulating layer 150 may have an upper surface disposed at a higher level than the upper surface of the active semiconductor layer 140. The gate insulating layer 150 may have an upper surface disposed at the same level as the upper surface of the cover insulating layer 136. In other embodiments, the gate insulating layer 150 may include at least one selected from a high-k dielectric material having a higher dielectric constant than silicon oxide, and a ferroelectric material. In some embodiments, the gate insulating layer 150 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AIO), or lead scandium tantalum oxide (PbScTaO).

The word line WL may be disposed on the second sidewall S12 of the first portion 140P1 and the upper surface of the second portion 140P2 of the plurality of active semiconductor layers 140 such that the gate insulating layer 150 is disposed between the word line WL and the second sidewall S12. In embodiments, the word line WL may have an L-shaped vertical cross-section. In embodiments, the bit line BL may include Ti, TIN, Ta, TaN, Mo, Ru, W, WN, TiSIN, WSiN, polysilicon, or a combination thereof.

A first insulating liner 162 and a second insulating liner 164 may be disposed on sidewalls of two word lines WL spaced apart from each other within the mold opening 130H, and a buried insulating layer 166 that fills a space between the two word lines WL spaced apart from each other, on the first insulating liner 162 and the second insulating liner 164, may be arranged. For example, the first insulating liner 162 and the second insulating liner 164 may include silicon nitride, and the buried insulating layer 166 may include silicon oxide.

A landing pad 170 may be disposed on the mold structure 130 and an upper surface of the buried insulating layer 166. The landing pad 170 may include an upper portion 170U and a bottom portion 170B, and the upper portion 170U of the landing pad 170 may be disposed on the mold structure 130 and the upper surface of the buried insulating layer 166, and the bottom portion 170B of the landing pad 170 may be disposed inside a landing pad recess space 170R.

For example, the landing pad recess space 170R may be defined on an upper surface of the first portion 140P1 of the active semiconductor layer 140, between the first and second sidewalls 130H1 and 130H2 of the mold opening 130H and the gate insulating layer 150. The bottom portion 170B of the landing pad 170 may be disposed between the gate insulating layer 150 and the interface insulating layer 138 within the landing pad recess space 170R. A bottom surface of the bottom portion 170B of the landing pad 170 may contact the upper surface of the first portion 140P1 of the active semiconductor layer 140. The bottom surface of the bottom portion 170B of the landing pad 170 may be disposed at the same level as the bottom surface of the cover insulating layer 136 and a bottom surface of the interface insulating layer 138.

In some embodiments, the landing pad 170 may have a T-shaped vertical cross-section, and the width of the upper portion 170U of the landing pad 170 may be greater than the width of the bottom portion 170B of the landing pad 170. In embodiments, the landing pad 170 may include Ti, TiN, Ta, TaN, W, WN, TiSIN, WSiN, polysilicon, or a combination thereof.

In further embodiments, the interface insulating layer 138 may be disposed to cover the sidewall of the cover insulating layer 136 within the landing pad recess space 170R, and accordingly, the bottom portion 170B of the landing pad 170 and the cover insulating layer 136 may not be in contact with each other. For example, as illustrated in FIG. 5, the entire sidewall of the cover insulating layer 136 facing the bottom portion 170B of the landing pad 170 may be covered by the interface insulating layer 138.

In a manufacturing process according to embodiments, a recess process may be performed on the upper side of the first portion 140P1 of the active semiconductor layer 140 disposed between the mold structure 130 and the buried insulating layer 166, to thereby lower the height of the first portion 140P1 of the active semiconductor layer 140 and form the landing pad recess space 170R. Then, by performing an oxygen annealing process through the upper surface of the first portion 140P1 of the active semiconductor layer 140 exposed in the landing pad recess space 170R, oxygen vacancies included in the active semiconductor layer 140 may be passivated, thereby adjusting the carrier concentration of the active semiconductor layer 140. As a result of the oxygen annealing process performed on the upper surface of the cover insulating layer 136 exposed on an inner wall of the landing pad recess space 170R, the interface insulating layer 138 may be formed on the sidewall and the upper surface of the cover insulating layer 136.

A landing pad isolation insulating layer 172 covering the landing pad 170 may be disposed on the mold structure 130 and the upper surface of the buried insulating layer 166. The landing pad isolation insulating layer 172 may fill spaces between adjacent landing pads 170 and cover upper surfaces of the landing pads 170, and the landing pad isolation insulating layer 172 may have an upper surface arranged at a higher level than the upper surfaces of the landing pads 170. In other embodiments, the landing pad isolation insulating layer 172 may have an upper surface disposed at the same level as the upper surfaces of the landing pads 170.

The storage node 180 may be disposed on the landing pad isolation insulating layer 172. In some embodiments, the storage node 180 may be of a capacitor type (e.g., for a DRAM memory cell) and may include, for example, a lower electrode 182, a capacitor dielectric layer 184, and an upper electrode 186. The lower electrode 182 may be disposed on the upper surfaces of the landing pads 170 and may extend in the vertical direction Z. The capacitor dielectric layer 184 may be disposed on a sidewall of the lower electrode 182, and the upper electrode 186 may cover the lower electrode 182 on the capacitor dielectric layer 184.

According to the embodiments described above, an oxygen annealing process may be performed through the upper surface of the active semiconductor layer 140 exposed in the landing pad recess space 170R, and thus, the carrier concentration of the active semiconductor layer 140 may be adjusted, and accordingly, the semiconductor device 100 may have excellent electrical performance.

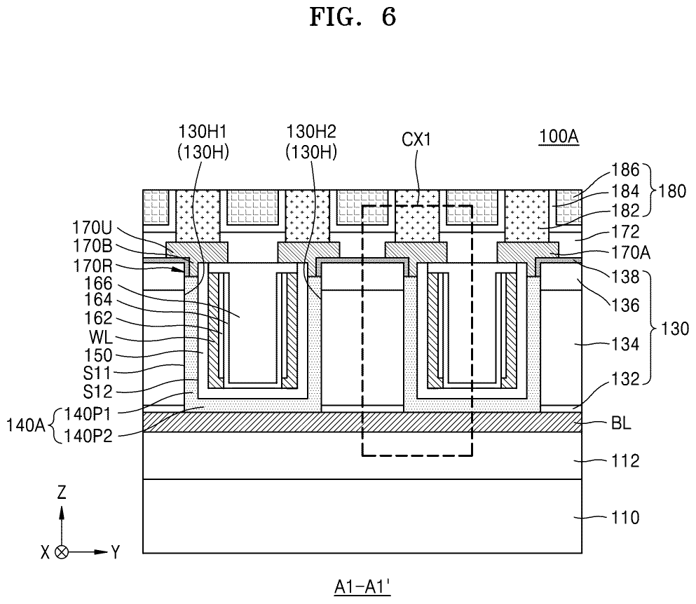

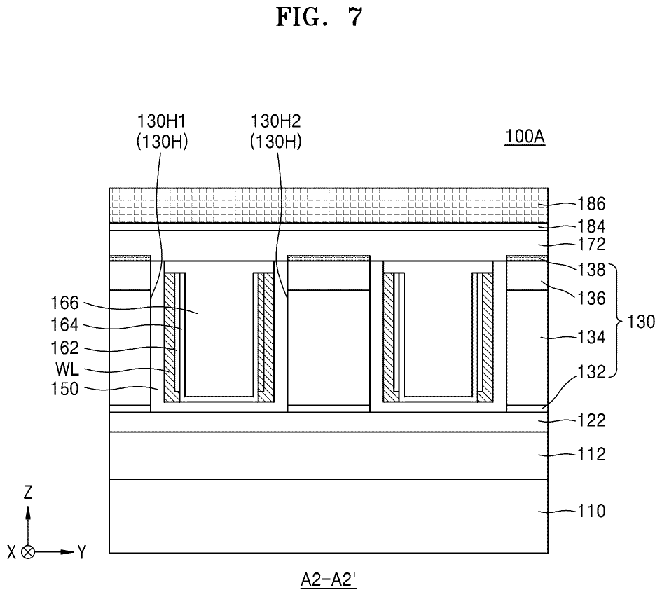

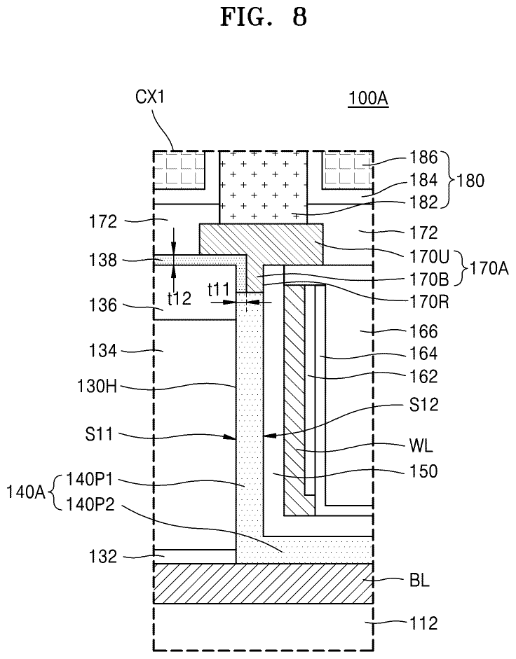

FIGS. 6 and 7 are cross-sectional views illustrating a semiconductor device 100A according to embodiments, and FIG. 8 is an enlarged view of portion CX1 of FIG. 6. In FIGS. 6 to 8, the same reference numerals as those in FIGS. 1 to 5 indicate the same components. Referring to FIGS. 6 to 8, the upper surface of the active semiconductor layer 140 may be disposed at a higher level than the upper surface of the mold insulating layer 134. For example, the upper surface of the active semiconductor layer 140 may be higher than the bottom surface of the cover insulating layer 136 and may be disposed at a lower level than the upper surface of the cover insulating layer 136. A landing pad 170A may include an upper portion 170U and a bottom portion 170B, and the bottom portion 170B of the landing pad 170A may be disposed inside the landing pad recess space 170R.

In some embodiments, the interface insulating layer 138 may be disposed to cover a portion of the sidewall of the cover insulating layer 136 within the landing pad recess space 170R, and, for example, a lower portion of the sidewall of the cover insulating layer 136 may not be covered by the interface insulating layer 138 and may be in contact with the upper side of the first portion 140P1 of the active semiconductor layer 140. The upper side of the sidewall of the cover insulating layer 136 may be covered by the interface insulating layer 138 and thus may not be in contact with the bottom portion 170B of the landing pad 170A.

In a manufacturing process according to embodiments, a recess process may be performed on the upper side of the first portion 140P1 of the active semiconductor layer 140 disposed between the mold structure 130 and the buried insulating layer 166 to thereby lower the height of the first portion 140P1 of the active semiconductor layer 140 and form the landing pad recess space 170R. Here, the amount of etching in the recess process may be adjusted such that the upper surface of the active semiconductor layer 140 is at a lower level than the upper surface of the cover insulating layer 136 and at a higher level than the upper surface of the mold insulating layer 134.

Then, by performing an oxygen annealing process through the upper surface of the first portion 140P1 of the active semiconductor layer 140 exposed in the landing pad recess space 170R, oxygen vacancies included in the active semiconductor layer 140 may be passivated, thereby adjusting the carrier concentration of the active semiconductor layer 140. Here, as a result of an oxygen annealing process performed on a portion of the upper surface and the sidewall of the cover insulating layer 136 exposed at the inner wall of the landing pad recess space 170R, a portion of the cover insulating layer 136 may be oxidized to thereby form the interface insulating layer 138.

A sidewall of the interface insulating layer 138 exposed in the landing pad recess space 170R may be aligned with a lower sidewall of the cover insulating layer 136, and the bottom surface of the interface insulating layer 138 may be arranged at a higher vertical level than the bottom surface of the cover insulating layer 136.

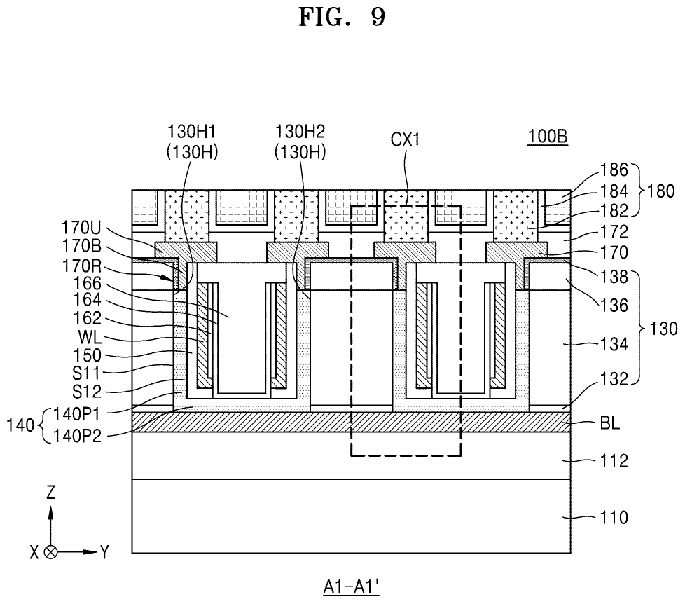

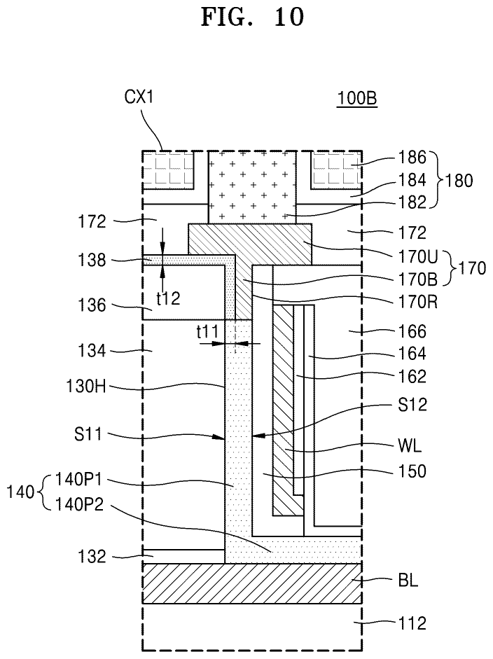

FIG. 9 is a cross-sectional view of a semiconductor device 100B according to embodiments, and FIG. 10 is an enlarged view of portion CX1 of FIG. 9. In FIGS. 9 and 10, the same reference numerals as those in FIGS. 1 to 8 indicate the same components. Referring to FIGS. 9 and 10, the gate insulating layer 150 and the word line WL may have an L-shaped vertical cross-section, and the second insulating liner 164 may cover the sidewall of the word line WL and a sidewall of the gate insulating layer 150 and extend downwards to extend to the upper surface of the second portion 140P2 of the active semiconductor layer 140.

According to embodiments, a portion of the active semiconductor layer 140 constituting the first cell transistor CTR1 (see FIG. 2) within one mold opening 130H may be connected to a portion of the active semiconductor layer 140 constituting the second cell transistor CTR2 (see FIG. 2) (for example, the active semiconductor layer 140 is shared between the first cell transistor CTR1 and the second cell transistor CTR2), and a portion of the gate insulating layer 150 constituting the first cell transistor CTR1 within one mold opening 130H may be disposed apart from a portion of the gate insulating layer 150 constituting the second cell transistor CTR2. In addition, within one mold opening 130H, the portion of the gate insulating layer 150 constituting the first cell transistor CTR1 may have a mirror symmetrical shape with respect to the portion of the gate insulating layer 150 constituting the second cell transistor CTR2.

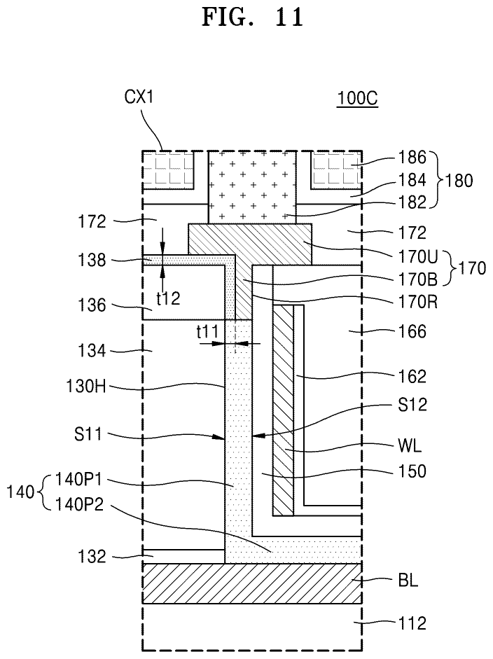

FIG. 11 is a cross-sectional view illustrating a semiconductor device 100C according to embodiments. In FIG. 11, the same reference numerals as those in FIGS. 1 to 10 indicate the same components. Referring to FIG. 11, the word line WL may have a vertical cross-section of a rectangular shape, and the upper and lower widths of the word line WL may be substantially the same. Also, the second insulating liner 164 described with reference to FIGS. 1 to 5 may be omitted and the buried insulating layer 166 may be disposed on the sidewall and upper surface of the first insulating liner 162.

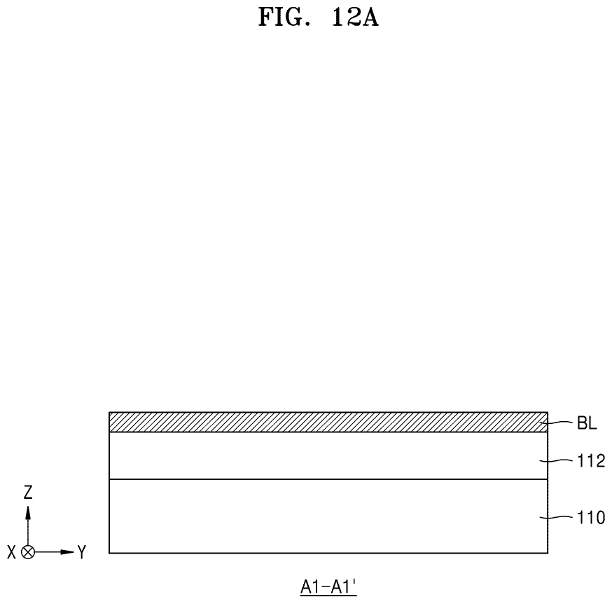

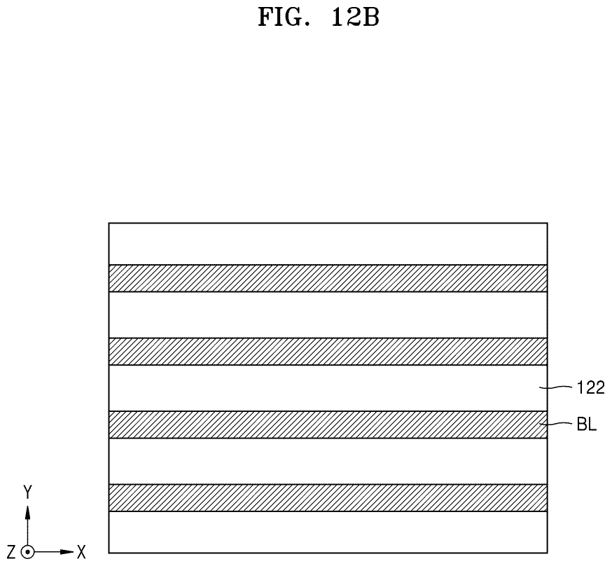

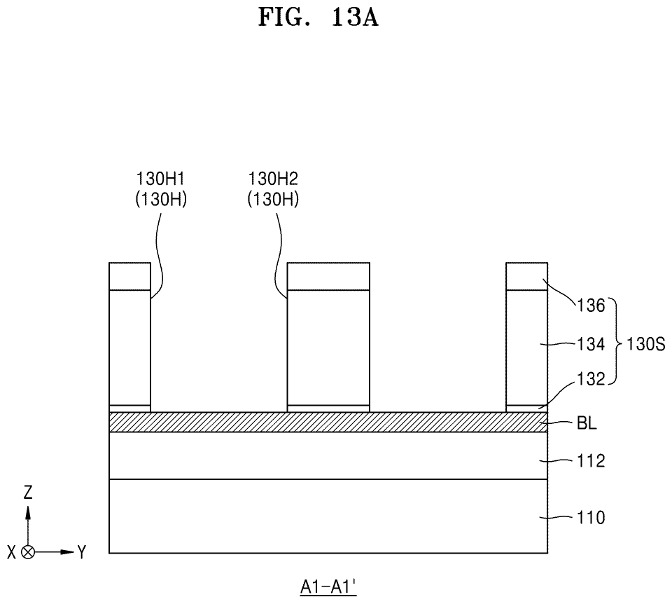

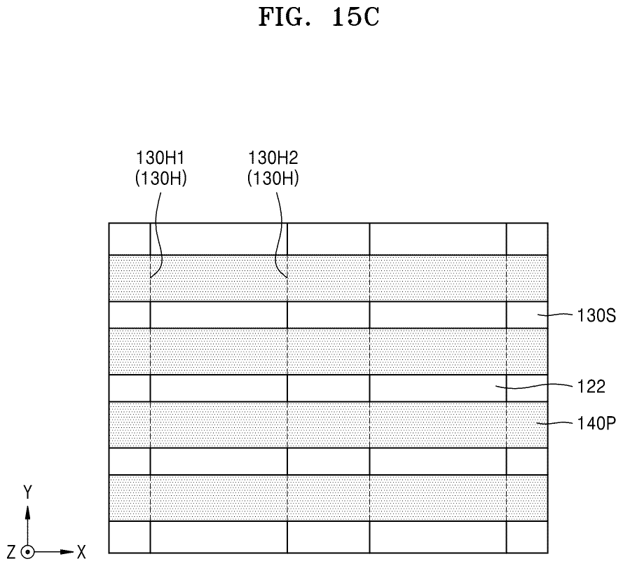

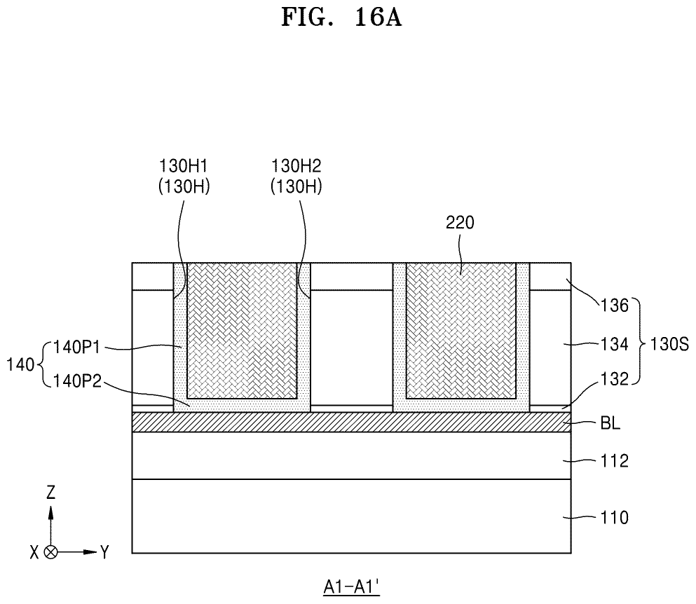

FIGS. 12A to 23 are schematic diagrams showing a method of manufacturing the semiconductor device 100 according to embodiments, where FIGS. 12A, 13A, 14, 15A, 16A, 17 to 21A, 22, and 23 are cross-sectional views taken along line A1-A1′ of FIG. 2, FIGS. 15B, 16B, and 21B are cross-sectional views taken along line A2-A2′ of FIG. 2, and FIGS. 12B, 13B, 15C, and 16C are top views of FIGS. 12A, 13A, 15A, and 16A. In FIGS. 12A to 23, the same reference numerals as those in FIGS. 1 to 11 indicate the same components.

Referring to FIGS. 12A and 12B, the lower insulating layer 112 is formed on the substrate 110. Thereafter, the bit line isolation insulating layer 122 may be formed on the lower insulating layer 112 to fill a space between the plurality of bit lines BL extending in the second horizontal direction Y.

In some embodiments, the bit line isolation insulating layer 122 may be formed on the lower insulating layer 112, and the bit line isolation insulating layer 122 may be patterned using a mask pattern (not shown) to form a bit line-forming space (not shown), and a conductive layer is formed within the bit line-forming space, and the upper side of the conductive layer may be removed so that the upper surface of the bit line isolation insulating layer 122 is exposed to thereby form the plurality of bit lines BL.

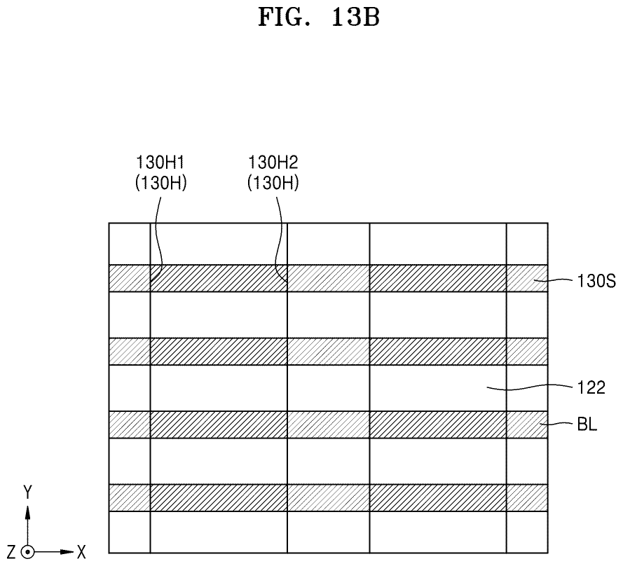

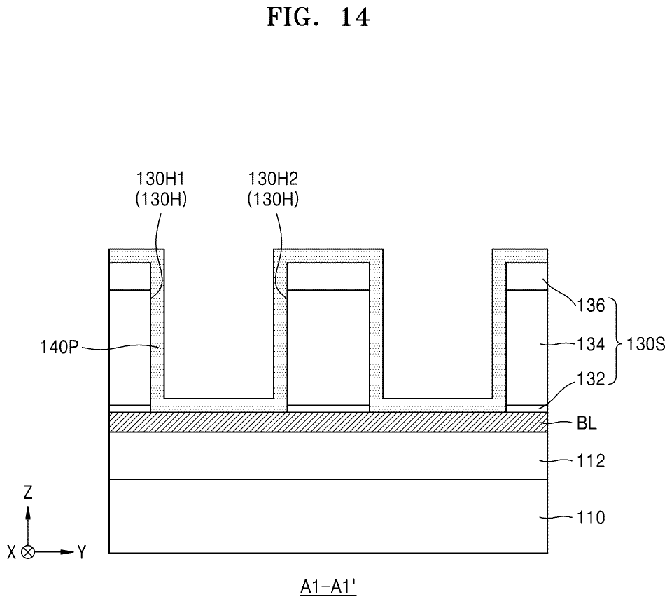

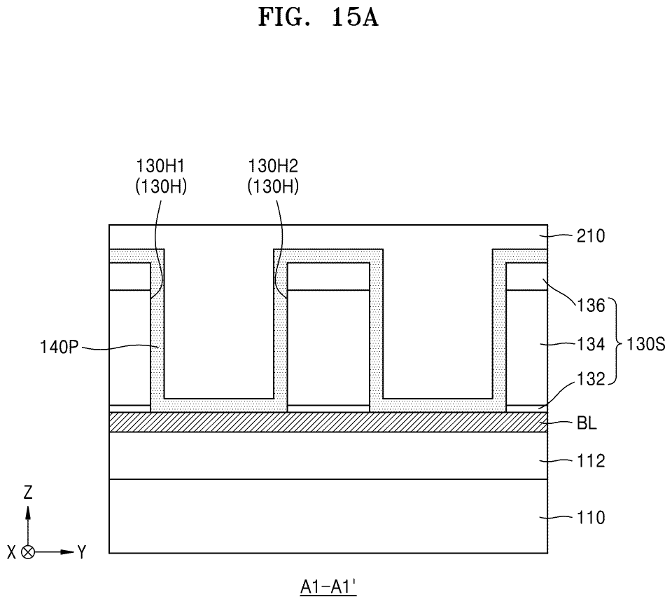

Referring to FIGS. 13A and 13B, a mold stack 130S may be formed on the plurality of bit lines BL and the bit line isolation insulating layer 122. As shown, this mold stack 130S may include the etch stop layer 132, the mold insulating layer 134, and the cover insulating layer 136. For example, the etch stop layer 132 may be formed using silicon nitride, the mold insulating layer 134 may be formed using silicon oxide, and the cover insulating layer 136 may be formed using silicon nitride.

Then, a mask pattern (not shown) may be formed on the mold stack 130S, and the plurality of mold openings 130H may be formed using the mask pattern as an etch mask. The upper surface of the bit line BL and the upper surface of the bit line isolation insulating layer 122 may be exposed at the bottom of the plurality of mold openings 130H. The plurality of mold openings 130H may be arranged to extend in the first horizontal direction X, and each of the plurality of mold openings 130H may include the first sidewall 130H1 and the second sidewall 130H2 that extend in the first horizontal direction X and are opposite to each other.

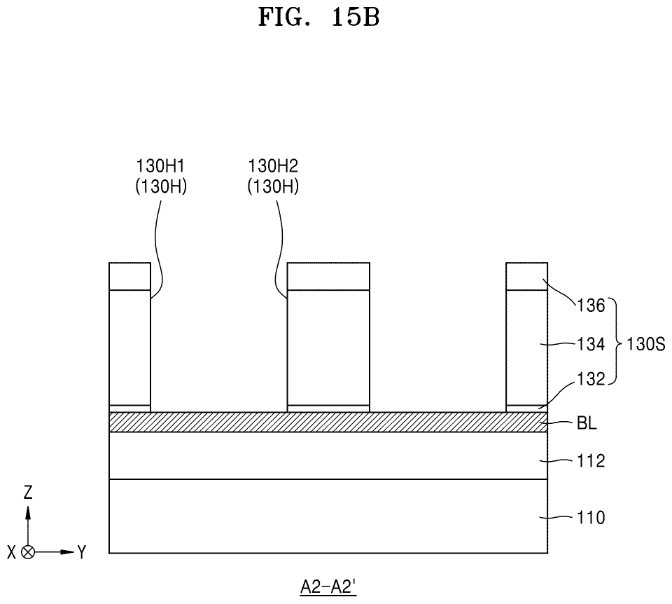

Referring to FIG. 14, a preliminary active semiconductor layer 140P may be formed on the mold stack 130S to conformally cover the inner wall of the mold opening 130H. This preliminary active semiconductor layer 140P may be formed using an oxide semiconductor material. For example, the preliminary active semiconductor layer 140P may include at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), and magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), and tin oxide (SnₓO). In some embodiments, the preliminary active semiconductor layer 140P may be formed using at least one of a chemical vapor deposition (CVD) process, a low pressure CVD process, a plasma enhanced CVD process, a metal organic CVD (MOCVD) process, and an atomic layer deposition process.

Referring to FIGS. 15A to 15C, a first mask layer 210 may be formed on the preliminary active semiconductor layer 140P. The first mask layer 210 having a sufficiently thick thickness to entirely fill the mold opening 130H may be formed.

Thereafter, a mask pattern (not shown) may be formed on the first mask layer 210, and a portion of the preliminary active semiconductor layer 140P may be removed using the mask pattern and the first mask layer 210 as an etch mask. For example, the mask pattern may have a line shape extending in the first horizontal direction X, and accordingly, the preliminary active semiconductor layer 140P may also be left on the inner wall of the mold opening 130H and an upper surface of the mold stack 130P to extend in the first horizontal direction X. Also, as a portion of the preliminary active semiconductor layer 140P is removed, the upper surface of the bit line isolation insulating layer 122 may be exposed again to the bottom of the mold opening 130H.

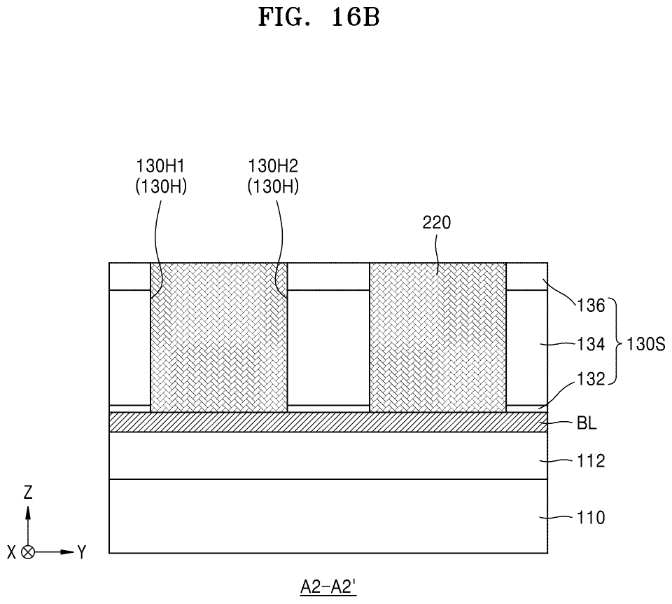

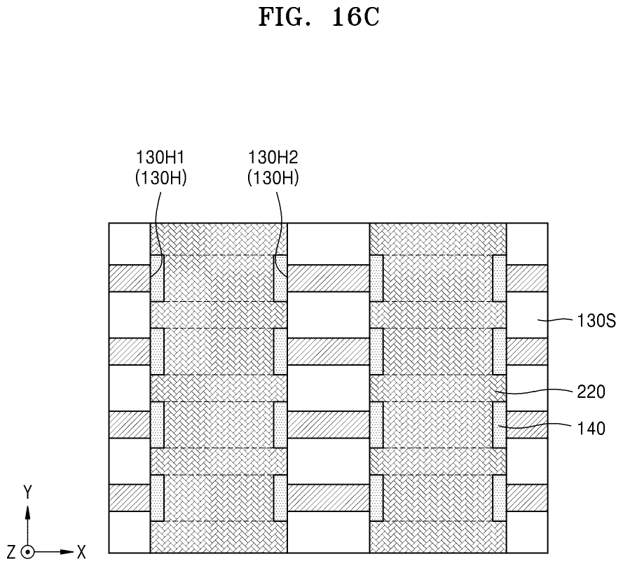

Referring to FIGS. 16A to 16C, the first mask layer 210 may be removed. Then, a second mask layer 220 may be formed on the mold stack 130S and the preliminary active semiconductor layer 140P. The second mask layer 220 having a thickness sufficient to completely fill the mold opening 130H may be formed, and thus, the upper surface of the preliminary active semiconductor layer 140P disposed on the upper surface of the mold stack 130S may be covered by the second mask layer 220.

Thereafter, a planarization process may be performed on the upper side of the second mask layer 220 to remove a portion of the preliminary active semiconductor layer 140P disposed on the upper surface of the mold stack 130S (e.g., the cover insulating layer 136) and leave the preliminary active semiconductor layer 140P on the inner wall of the mold opening 130H. In order that one active semiconductor layer 140 is disposed in a portion where one mold opening 130H and one bit line BL intersect with each other as the portion of the preliminary active semiconductor layer 140P disposed on the upper surface of the mold stack 130S (e.g., the upper surface of the cover insulating layer 136) is removed, a plurality of active semiconductor layers 140 spaced apart from each other in the first horizontal direction X and the second horizontal direction Y may be defined.

The active semiconductor layer 140 may include the first portion 140P1 disposed on the first and second sidewalls 130H1 and 130H2 of the mold opening 130H and the second portion 140P2 that is disposed on the bottom of the mold opening 130H and is continuously connected to the first portion 140P1. The active semiconductor layer 140 may have a U-shaped vertical cross-section.

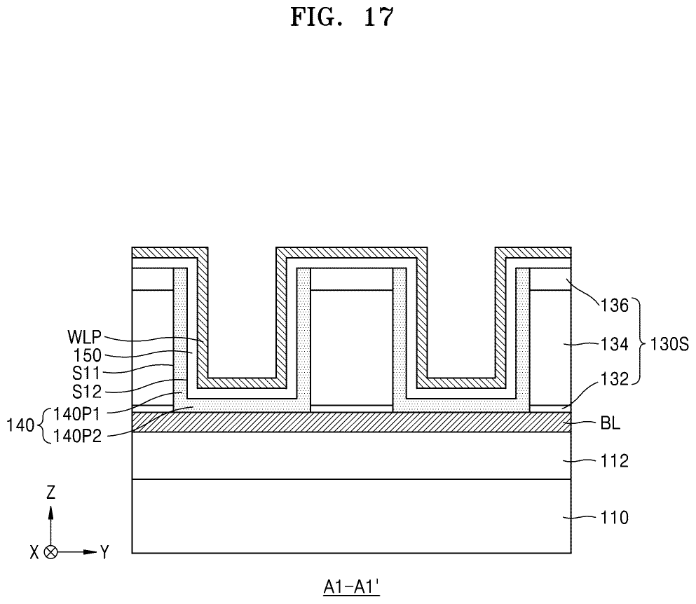

Referring to FIG. 17, the second mask layer 220 may be removed. Then, the gate insulating layer 150 may be formed on the plurality of active semiconductor layers 140. In some embodiments, the gate insulating layer 150 may include at least one selected from a high-k dielectric material having a higher dielectric constant than silicon oxide, and a ferroelectric material. In some embodiments, the gate insulating layer 150 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AIO), or lead scandium tantalum oxide (PbScTaO).

A word line metal layer WLP may be formed on the gate insulating layer 150. In some cases, this word line metal layer WLP may be formed using Ti, TiN, Ta, TaN, Mo, Ru, W, WN, TiSIN, WSiN, polysilicon, or a combination thereof.

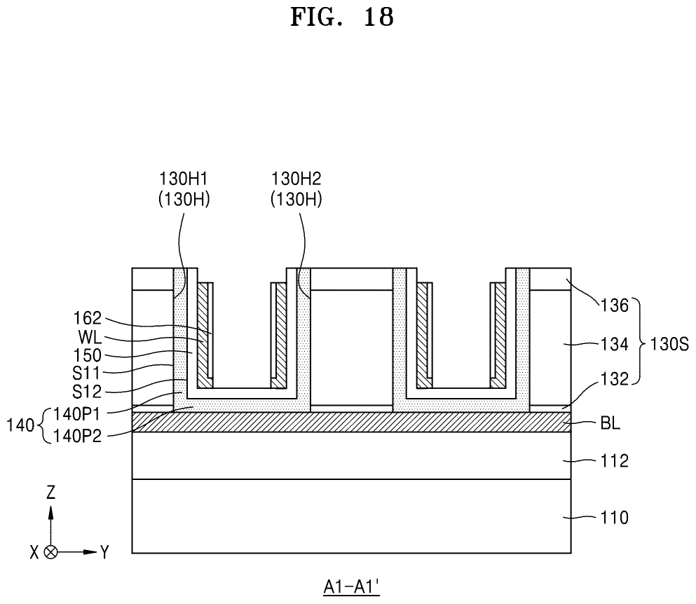

Referring to FIG. 18, the first insulating liner 162 may be formed on the word line metal layer WLP, and an anisotropic etching process may be performed on the word line metal layer WLP and the first insulating liner 162 to remove a portion of the word line metal layer WLP disposed on the bottom of the mold opening 130H and leave the word line WL on the first sidewall 130H1 and the second sidewall 130H2 of the mold opening 130H. In addition, a portion of the word line metal layer WLP disposed on the upper surface of the mold stack 130P may also be removed by the anisotropic etching process. After the anisotropic etching process, two word lines WL may be arranged apart from each other and disposed on the first sidewall 130H1 and the second sidewall 130H2 of the plurality of mold openings 130H, respectively.

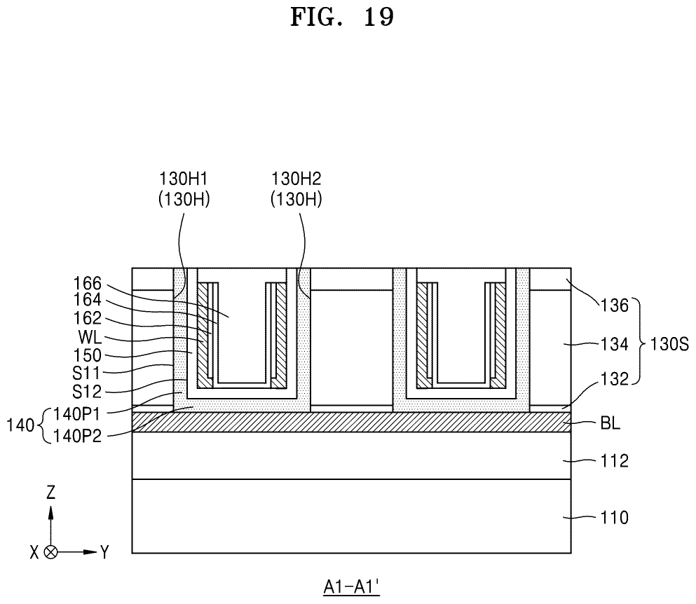

Referring to FIG. 19, the second insulating liner 164 and the buried insulating layer 166 may be formed inside the mold opening 130H. The second insulating liner 164 may be disposed on the upper surface of the active semiconductor layer 140 disposed at the bottom of the mold opening 130H, for example, on the second portion 140P2 of the active semiconductor layer 140. The buried insulating layer 166 may fill the mold opening 130H on the second insulating liner 164.

In embodiments, the buried insulating layer 166 may have an upper surface disposed at the same level as the upper surface of the mold stack 130S, and the upper surface of the first portion 140P1 of the active semiconductor layer 140 and the upper surface of the gate insulating layer 150 may also be disposed at the same level as the upper surface of the mold stack 130S.

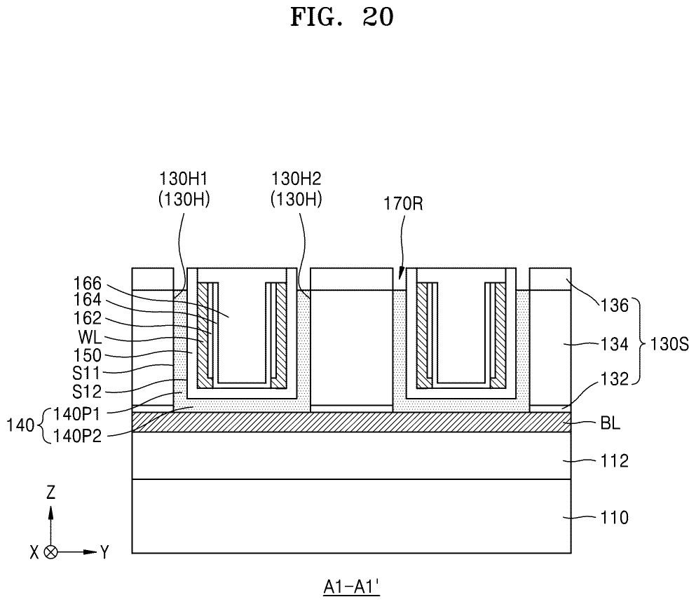

Referring to FIG. 20, a portion of the upper side of the active semiconductor layer 140 may be removed through an etch-back process to form the landing pad recess space 170R. The landing pad recess space 170R may refer to a space between the upper surfaces of the active semiconductor layers 140 between the upper side of the mold stack 130S and the buried insulating layer 166. The upper surface of the active semiconductor layer 140 may be disposed at the bottom of the landing pad recess space 170R.

In embodiments, the landing pad recess space 170R may be formed to a depth that exposes the sidewall of the cover insulating layer 136, and the upper surface of the first portion 140P1 of the active semiconductor layer 140 may be disposed at the same level as the bottom surface of the cover insulating layer 136.

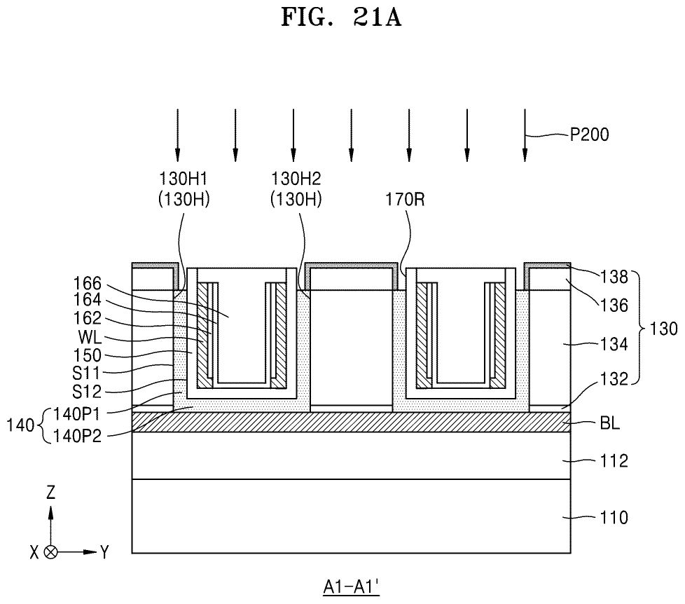

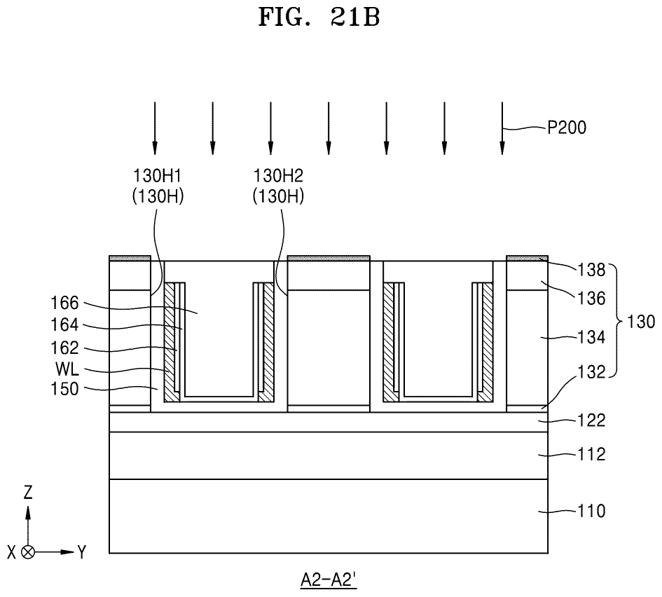

Referring to FIGS. 21A and 21B, an oxygen annealing process P200 may be performed through the upper surface of the active semiconductor layer 140 exposed in the landing pad recess space 170R. In some cases, this oxygen annealing process P200 may include exposing the upper surface of the active semiconductor layer 140 to an oxygen-containing atmosphere. For example, the oxygen annealing process P200 may include supplying at least one of oxygen gas, atmospheric air, ozone, or oxygen plasma to the active semiconductor layer 140 so that oxygen atoms may penetrate through the upper surface of the active semiconductor layer 140 exposed in the landing pad recess space 170R.

In embodiments, the oxygen annealing process P200 may be performed under atmospheric pressure or elevated pressure. In some embodiments, the oxygen annealing process P200 may be performed sequentially under vacuum and atmospheric pressure. In embodiments, the oxygen annealing process P200 may be performed at room temperature or elevated temperature. In embodiments, the oxygen annealing process P200 may be performed for about several minutes to about several hours.

In embodiments, by performing the oxygen annealing process P200, oxygen atoms may penetrate and/or diffuse into the active semiconductor layer 140, and oxygen vacancies contained within the active semiconductor layer 140 may be passivated, and the carrier concentration of the active semiconductor layer 140 may be adjusted.

In embodiments, as the oxygen annealing process P200 is performed through the upper surface of the active semiconductor layer 140 exposed in the landing pad recess space 170R, a sufficient amount of oxygen atoms may be supplied into the active semiconductor layer 140.

In embodiments, as a result of an oxygen annealing process performed on the upper surface of the cover insulating layer 136 exposed at the inner wall of the landing pad recess space 170R, a portion of the cover insulating layer 136 may be oxidized to form the interface insulating layer 138. The interface insulating layer 138 may be formed on the entire upper surface of the cover insulating layer 136 exposed during the oxygen annealing process P200. Additionally, the interface insulating layer 138 may be formed on the sidewall of the cover insulating layer 136 exposed within the landing pad recess space 170R during the oxygen annealing process P200.

In embodiments, the interface insulating layer 138 formed on the sidewall of the cover insulating layer 136 may have the first thickness t11 (see FIG. 5), and the interface insulating layer 138 formed on the upper surface of the cover insulating layer 136 may have the second thickness t12 (see FIG. 5). In embodiments, the first thickness t11 and the second thickness t12 may be in a range from about several angstroms to about tens of angstroms. In some embodiments, the first thickness t11 may be substantially equal to the second thickness t12. In some embodiments, the first thickness t11 may be less than the second thickness t12. Here, the structure in which the etch stop layer 132, the mold insulating layer 134, the cover insulating layer 136, and the interface insulating layer 138 are sequentially disposed is referred to as the mold structure 130.

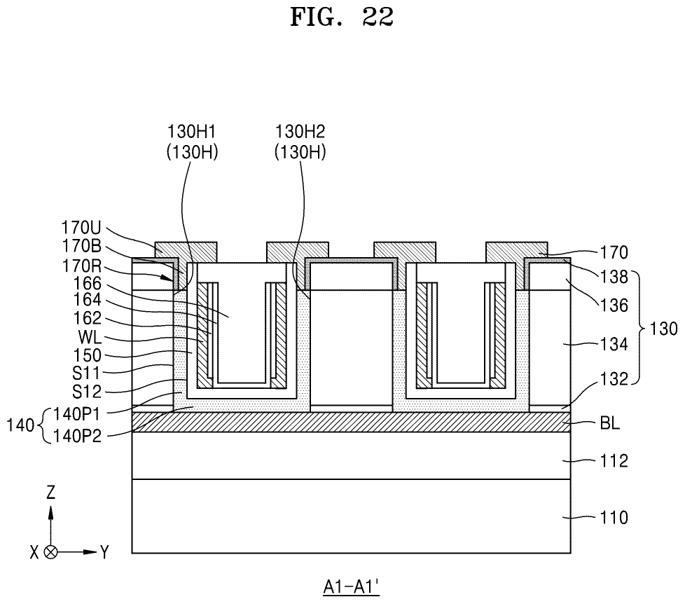

Referring to FIG. 22, the landing pad 170 may be formed on the mold structure 130 and the buried insulating layer 166. The landing pad 170 may fill the landing pad recess space 170R and may contact the upper surface of the first portion 140P1 of the active semiconductor layer 140. In some cases, the landing pad 170 may include Ti, TIN, Ta, TaN, W, WN, TiSIN, WSIN, polysilicon, or a combination thereof. And, in some embodiments, before forming the landing pad 170 in the landing pad recess space 170R, a contact area may also be formed by implanting impurity ions into the upper surface of the first portion 140P1 of the active semiconductor layer 140 exposed in the landing pad recess space 170R.

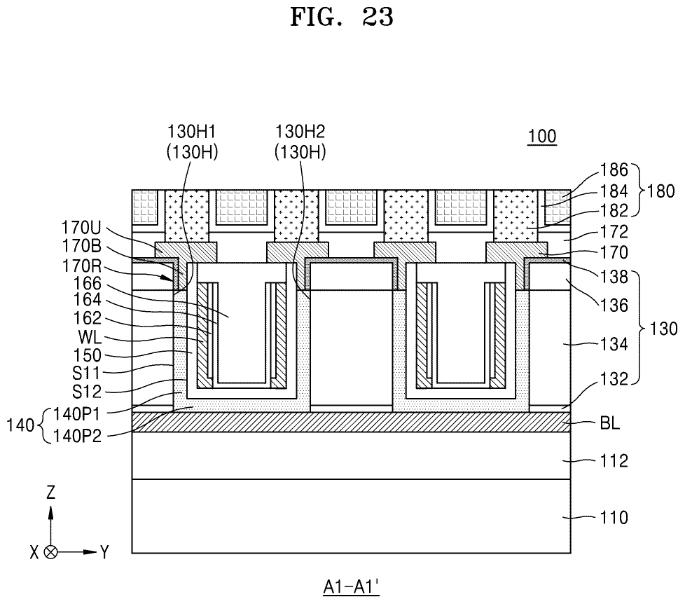

Referring to FIG. 23, the landing pad isolation insulating layer 172 covering the landing pad 170 may be formed on the mold structure 130 and the buried insulating layer 166. The landing pad isolation insulating layer 172 may be formed using silicon nitride. Then, the lower electrode 182, the capacitor dielectric layer 184, and the upper electrode 186 may be sequentially formed on the landing pad 170 and the landing pad isolation insulating layer 172.

The semiconductor device 100 may be completely formed by performing the process described above. In addition, by performing the oxygen annealing process P200, oxygen atoms may be made to penetrate and/or diffuse into the active semiconductor layer 140 and thus oxygen vacancies within the active semiconductor layer 140 may be passivated, or the carrier concentration of the active semiconductor layer 140 may be adjusted. Accordingly, the semiconductor device 100 may have excellent electrical performance.

In other embodiments, in the process described with reference to FIG. 20, the landing pad recess space 170R may be formed to a depth that exposes only the upper portion of the sidewall of the cover insulating layer 136, and the upper surface of the first portion 140P1 of the active semiconductor layer 140A (see FIG. 6) may be disposed at a higher level than the bottom surface of the cover insulating layer 136. In this case, when performing the oxygen annealing process P200 in the process described with reference to FIG. 21, the interface insulating layer 138 may be formed only on the upper portion of the sidewall of the cover insulating layer 136 exposed by the landing pad recess space 170R. The lower portion of the sidewall of the cover insulating layer 136 may be covered by the active semiconductor layer 140A and may not be exposed to the oxygen atmosphere, and the interface insulating layer 138 may not be formed on the lower portion of the sidewall of the cover insulating layer 136. In this case, the semiconductor device 100A described with reference to FIGS. 6 to 8 may be manufactured.

While the inventive concept has been particularly shown and described with reference to embodiments thereof, it will be understood that various changes in form and details may be made therein without departing from the spirit and scope of the following claims.

1. A semiconductor device, comprising:
a bit line extending in a first horizontal direction across an underlying substrate;
a mold structure, which extends on the bit line and has a mold opening therein that extends in a second horizontal direction perpendicular to the first horizontal direction, said mold structure including a mold insulating layer, a cover insulating layer extending on the mold insulating layer, and an interface insulating layer extending on an upper surface of and on at least a portion of a sidewall of the cover insulating layer;
an active semiconductor layer including:
a first portion extending on an inner wall of the mold opening in the mold structure, and in a vertical direction perpendicular to an upper surface of the substrate, said first portion having a first sidewall in contact with a sidewall of the mold opening and a second sidewall extending opposite the first sidewall; and
a second portion connected to the bottom of the first portion and extending in the first horizontal direction and on an upper surface of the bit line;
a word line extending on the second sidewall of the active semiconductor layer and in the second horizontal direction; and
a gate insulating layer extending between the active semiconductor layer and the word line.

2. The device of claim 1, further comprising:
a landing pad extending on an upper surface of the first portion of the active semiconductor layer;
wherein the interface insulating layer extends between the landing pad and the cover insulating layer; and
wherein the landing pad is not in contact with the cover insulating layer.

3. The device of claim 1, wherein the active semiconductor layer has a U-shaped vertical cross-section; and wherein the word line has an L-shaped vertical cross-section.

4. The device of claim 1, further comprising:
a landing pad extending on an upper surface of the first portion of the active semiconductor layer;
wherein the landing pad includes an upper portion and a bottom portion;
wherein the bottom portion of the landing pad extends in a landing pad recess space defined between the mold structure and the gate insulating layer on an upper surface of the active semiconductor layer; and
wherein the upper portion of the landing pad is disposed on an upper surface of the mold structure.

5. The device of claim 4, wherein the upper portion of the landing pad has a first width in the first horizontal direction; wherein the bottom portion of the landing pad has a second width that is less than the first width in the first horizontal direction.

6. The device of claim 4, wherein the interface insulating layer extends from the upper surface of the cover insulating layer onto the sidewall of the cover insulating layer extending in the landing pad recess space; and wherein a portion of the interface insulating layer extending on the sidewall of the cover insulating layer is in contact with the landing pad.

7. The device of claim 6, wherein the first portion of the active semiconductor layer has an upper surface disposed at a same or lower level than a bottom surface of the cover insulating layer; and wherein the entire sidewall of the cover insulating layer extending in the landing pad recess space is covered by the interface insulating layer.

8. The device of claim 6,
wherein the first portion of the active semiconductor layer has an upper surface disposed at a higher level than a bottom surface of the cover insulating layer;
wherein an upper side of the sidewall of the cover insulating layer extending in the landing pad recess space is covered by the interface insulating layer; and
wherein a lower side of the sidewall of the cover insulating layer is in contact with a sidewall of the first portion of the active semiconductor layer.

9. The device of claim 4, further comprising:
a buried insulating layer extending on a sidewall of the word line and filling the mold opening; and
wherein a portion of a bottom surface of the upper portion of the landing pad is disposed on an upper surface of the buried insulating layer.

10. The device of claim 1, wherein a bottom surface of the landing pad is disposed at a same level as a bottom surface of the interface insulating layer.

11. The device of claim 1, wherein the interface insulating layer includes at least one of silicon oxynitride and silicon oxide.

12. The semiconductor device of claim 1, wherein the active semiconductor layer comprises at least one of indium gallium zinc oxide (InₓGa_{y}Zn_{z}O), indium tungsten oxide (InₓWyO), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide, (ZrₓZn_{y}Sn_{z}O), gallium zinc tin oxide (GaₓZn_{y}Sn_{z}O), aluminum zinc tin oxide (AlₓZn_{y}Sn_{z}O), and tin oxide (SnₓO).

13. A semiconductor device, comprising:
a bit line extending in a first direction, on an underlying substrate;
a mold structure having a mold opening therein that extends in a second direction, which is perpendicular to the first direction, said mold structure extending on the bit line and comprising a mold insulating layer, a cover insulating layer on the mold insulating layer, and an interface insulating layer on an upper surface of and on at least a portion of a sidewall of the cover insulating layer;
an active semiconductor layer including a first portion extending on an inner wall of the mold opening in the mold structure and extending in a vertical direction perpendicular to an upper surface of the substrate, and a second portion, which is connected to the bottom of the first portion and extends in the first direction;
a word line extending on the second sidewall of the active semiconductor layer and extending in the second horizontal direction;
a gate insulating layer extending between the active semiconductor layer and the word line; and
a landing pad electrically connected to an upper surface of the first portion of the active semiconductor layer, said landing pad comprising an upper portion extending on an upper surface of the mold structure and a bottom portion connected to the upper portion and extending in a landing pad recess space;
wherein a bottom surface of the bottom portion of the landing pad extends at a same level as a bottom surface of the interface insulating layer;
wherein the first portion includes a first sidewall in contact with a sidewall of the mold opening and a second sidewall extending opposite to the first sidewall; and
wherein the second portion extends on an upper surface of the bit line.

14. The device of claim 13, wherein the interface insulating layer extends from the upper surface of the cover insulating layer onto a sidewall of the cover insulating layer disposed in the landing pad recess space; and wherein a portion of the interface insulating layer disposed on the sidewall of the cover insulating layer is in contact with the bottom portion of the landing pad.

15. The device of claim 14, wherein the interface insulating layer extends between the bottom portion of the landing pad and the cover insulating layer; and wherein the bottom portion of the landing pad is not in contact with the cover insulating layer.

16. The device of claim 13, wherein the first portion of the active semiconductor layer has an upper surface disposed at a same or lower level than the bottom surface of the cover insulating layer; and wherein an entire sidewall of the cover insulating layer disposed in the landing pad recess space is covered by the interface insulating layer.

17. The device of claim 13, further comprising:
a buried insulating layer extending on a sidewall of the word line and filling the mold opening; and
wherein a portion of a bottom surface of the upper portion of the landing pad extends on an upper surface of the buried insulating layer.

18. The device of claim 13, wherein the interface insulating layer includes silicon oxynitride or silicon oxide, and
the cover insulating layer includes silicon nitride.

19. A semiconductor device, comprising:
a bit line extending in a first horizontal direction on a substrate;
a mold structure extending on the bit line and having a mold opening therein, which extends in a second direction perpendicular to the first horizontal direction, said mold structure comprising a mold insulating layer, a cover insulating layer disposed on the mold insulating layer, and an interface insulating layer disposed on an upper surface of and on at least a portion of a sidewall of the cover insulating layer;
an active semiconductor layer including a first portion disposed on an inner wall of the mold opening of the mold structure and extending in a vertical direction perpendicular to an upper surface of the substrate, and a second portion connected to the bottom of the first portion and extending in the first horizontal direction, wherein the second portion extends on an upper surface of the bit line, and the first portion includes a first sidewall in contact with a sidewall of the mold opening and a second sidewall opposite to the first sidewall, and wherein the active semiconductor layer has an upper surface extending at a lower level than an upper surface of the mold structure;
a word line extend on the second sidewall of the active semiconductor layer and extending in the second horizontal direction;
a gate insulating layer disposed between the active semiconductor layer and the word line;
a buried insulating layer extending on a sidewall of the word line and filling the mold opening;
a landing pad electrically connected to an upper surface of the first portion of the active semiconductor layer, said landing pad including an upper portion disposed on the upper surface of the mold structure and a bottom portion connected to the upper portion and disposed in a landing pad recess space; and
a storage node connected to the landing pad;
wherein the interface insulating layer extends from the upper surface of the cover insulating layer onto a sidewall of the cover insulating layer extending in the landing pad recess space.

20. The semiconductor device of claim 19,
wherein the first portion of the active semiconductor layer has an upper surface disposed at a same or lower level than a bottom surface of the cover insulating layer;
wherein an entire sidewall of the cover insulating layer disposed in the landing pad recess space is covered by the interface insulating layer; and
wherein the interface insulating layer extends between the bottom portion of the landing pad and the cover insulating layer and is not in contact with the cover insulating layer.

21.-25. (canceled)
